(19) United States
(12) Patent Application Publication
(10) Pub. No.: US 2019/0170808 A1
(43) Pub. Date: Jun. 6, 2019

(54) TESTING SYSTEM FOR MICRO LIGHTING DEVICE AND RELATED TESTING METHOD

(71) Applicant: ACER INCORPORATED, New Taipei City (TW)

(72) Inventors: Jui-Chieh Hsiang, New Taipei City (TW); Chih-Chiang Chen, New Taipei City (TW)

(21) Appl. No.: 15/889,222

(22) Filed: Feb. 6, 2018

(30) Foreign Application Priority Data
Dec. 6, 2017 (TW) 106142656

(51) Int. Cl. G01R 31/26; G01R 31/308

(52) U.S. Cl. CPC G01R 31/2635; G01R 31/308

(57) ABSTRACT

A testing system for a micro lighting device includes a test electrode, a carrier, a power supply, an optical receiver, and a judging unit. The carrier is used to hold the test electrode and adjust the distance between the test electrode and a first electrode of a luminance device in the micro lighting device. The power supply is configured to apply a first voltage to the test electrode and apply a second voltage to a second electrode of the luminance device. The optical device is configured to detect optical signals from the luminance device. The judging unit is configured to determine whether the luminance device is lit up according to the detecting result of the optical device.

### CROSS REFERENCE TO RELATED APPLICATION

This application claims priority of Taiwan Application No. 106142656 filed on 2017 Dec. 6.

### BACKGROUND OF THE INVENTION

### 1. Field of the Invention

The present invention is related to a testing system for micro lighting device and related testing method, and more particularly, to a testing system for micro LED and related testing method.

### 2. Description of the Prior Art

Compared to traditional incandescent bulbs, light-emitting diodes (LEDs) are advantageous in low power consumption, long lifetime, small size, no warm-up time, fast reaction speed, and the ability to be manufactured as small or array devices. In addition to outdoor displays, traffic signs, and liquid crystal display (LCD) backlight for various electronic devices such as mobile phones, notebook computers or personal digital assistants (PDAs), LEDs are also widely used as indoor/outdoor lighting devices in place of fluorescent of incandescent lamps.

The size of traditional LED arrays is the dimension of millimeters (mm). The size of micro LED arrays may be reduced to the dimension of micrometers (μm) while inheriting the same good performances regarding power consumption, brightness, resolution, color saturation, reaction speed, life time and efficiency. In a micro LED manufacturing process, a thin-film, miniaturized and array design is adopted so that multiple micro LEDs are fabricated in the dimension of merely 1-300 μm. Next, these micro LEDs are mass transferred to be disposed on another circuit board. Protection layers and upper electrodes may be formed in a physical deposition process before packaging the upper substrate. Since the manufacturing process of micro LEDs is very complicated, there is a need for a testing system and related testing method in order filter flawed micro LEDs.

### SUMMARY OF THE INVENTION

The present invention provides a testing system for use in a micro lighting device. The testing system includes a test electrode, a carrier, a power supply, an optical receiver, and a judging unit. The carrier is configured to hold the test electrode and adjust a distance between the test electrode and a first electrode of a luminance device in the micro lighting device. The power supply is configured to apply a first voltage to the first test electrode and apply a second voltage to a second electrode of the luminance device. The optical receiver is configured to detect an optical signal of the luminance device. The judging unit is configured to determine whether the luminance device is able to light up according to a detecting result of the optical receiver.

The present invention also provides a testing system for use in a micro lighting device. The testing system includes a power supply and a testing material layer. The power supply is configured to apply a first voltage to a first electrode of a luminance device in the micro lighting device and apply a second voltage to a second electrode of the luminance device. The testing material layer is disposed on the micro lighting device, wherein a color of the testing material layer is associated with at least one of luminous energy and thermal energy provided by the luminance device in the micro lighting device.

The present invention also provides a method of testing a micro lighting device. The method includes applying a first voltage to a first test electrode, applying a second voltage to a first electrode of a luminance device in the micro lighting device, adjusting a distance between the first test electrode and the luminance device until a second electrode of the luminance device is able to sense the first voltage, and determining whether the luminance device is lit up by detecting an optical signal from the luminance device.

The present invention also provides a method of testing a micro lighting device. The method includes applying a first voltage to a first test electrode, applying a second voltage to a second test electrode, adjusting a distance between the first test electrode and a luminance device in the micro lighting device until a first electrode of the luminance device is able to sense the first voltage, adjusting a distance between the second test electrode and the luminance device until a second electrode of the luminance device is able to sense the second voltage, and determining whether the luminance device is lit up by detecting an optical signal from the luminance device.

The present invention also provides a method of testing a micro lighting device. The method includes fabricating a plurality of luminance devices and then transferring the plurality of luminance devices to be disposed on a substrate, disposing a testing material layer on the plurality of luminance devices, wherein a color exhibited by the testing material layer on a region is associated with at least one of luminous energy and thermal energy received in the region, applying a first voltage to a first electrode of each luminance device and applying a second voltage to a second electrode of each luminance device, and determining whether each luminance device is lit up according to the color of each region corresponding to each luminance device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1A-1B are diagrams illustrating a testing system for micro lighting device according to an embodiment of the present invention.

FIGS. 2A-2B are diagrams illustrating a testing system for micro lighting device according to another embodiment of the present invention.

FIG. 3 and FIG. 4 are diagrams illustrating a testing system for micro lighting device according to another embodiment of the present invention.

### DETAILED DESCRIPTION

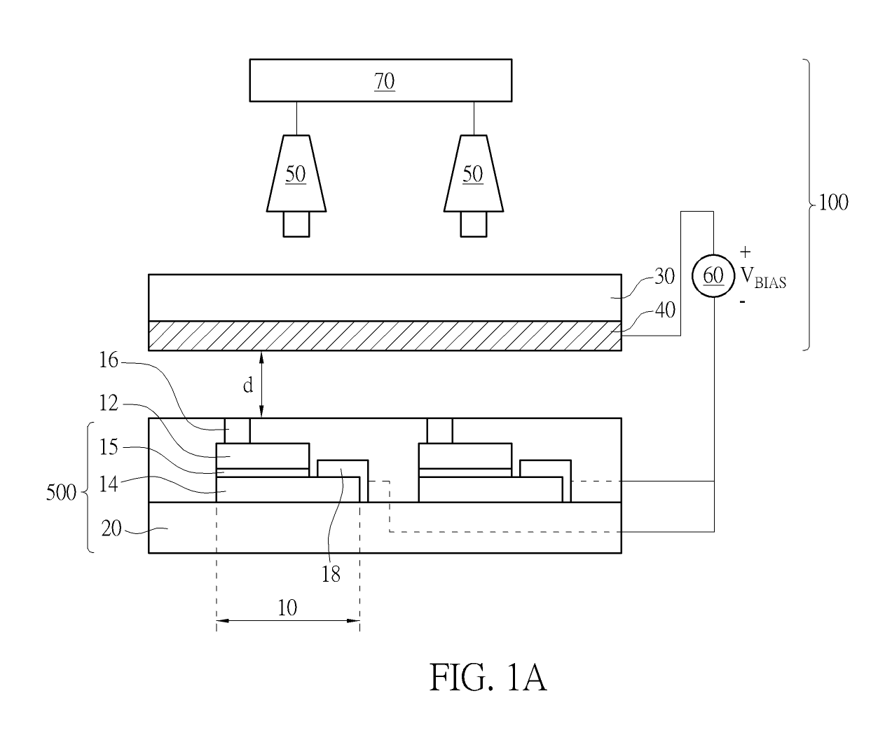

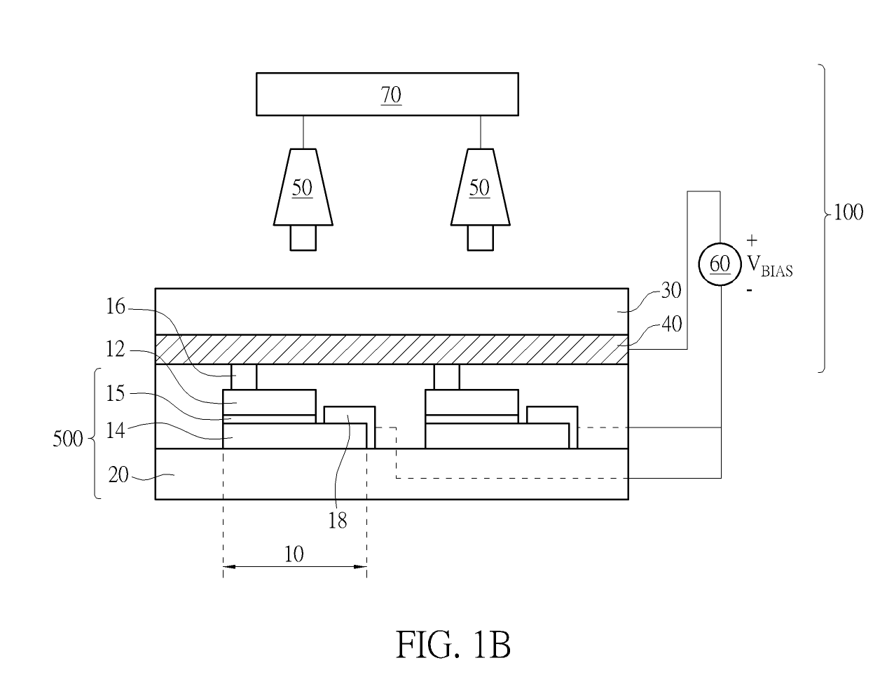

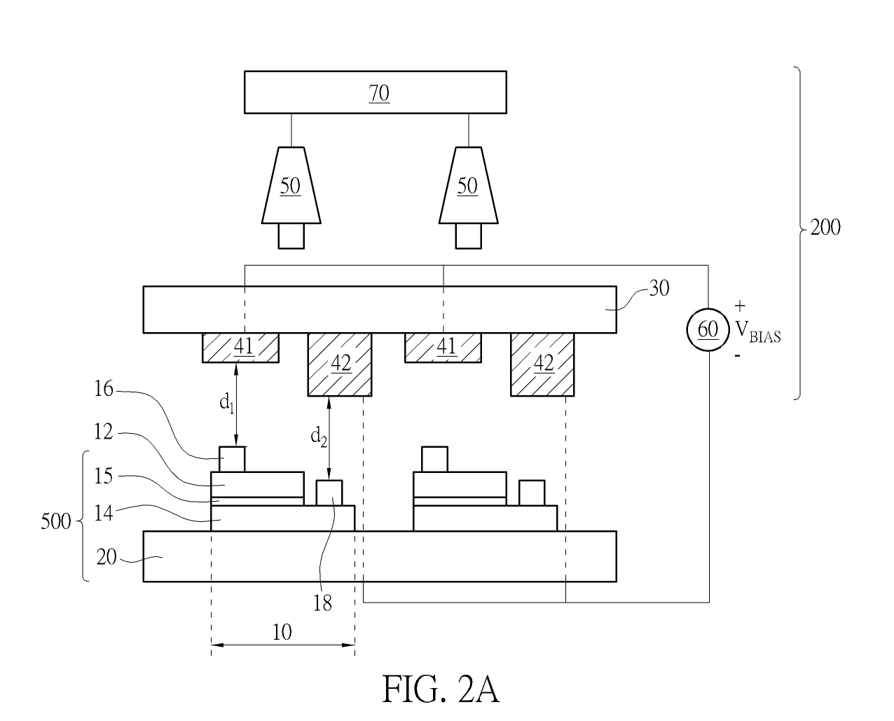

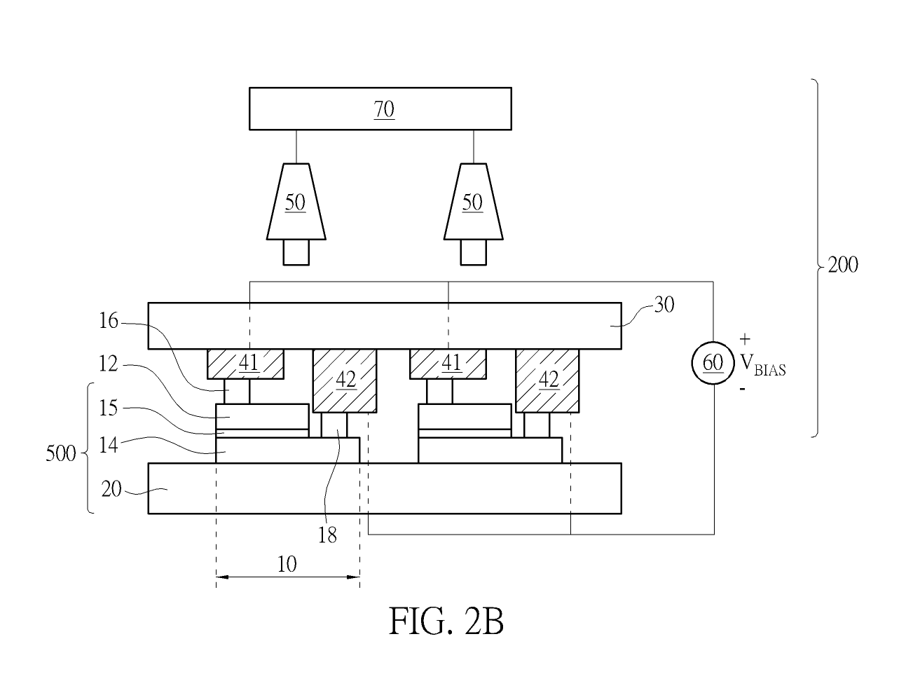

FIGS. 1A-1B and 2A-2B are diagrams illustrating testing system for micro lighting device according to embodiments of the present invention. The test system 100 depicted in FIGS. 1A-1B and the test system 200 depicted in FIGS. 2A-2B may be apply to a micro lighting device 500 in order to detect anomalies such as defects, contamination or missing materials in devices.

The micro lighting device 500 with a thin-film, miniaturized and array design includes a plurality of luminescent devices (only two luminescent devices 10 are depicted for illustrative purpose). The luminescent devices 10 are fabricated by combining P-type and N-type semiconductor materials before being mass transferred to be disposed on a substrate 20. Under normal condition, when a positive voltage is applied to the P-electrode and a negative voltage is applied to the N-electrode, electrons flow from the N-region towards the P-region and holes flow from the P-region towards the N-region due to the forward-bias voltage. These electrons and holes then combine in the PN junction of the luminescent layer, thereby emitting photons of light. In an embodiment of the present invention, each luminescent device 10 may be a micro LED device which includes a P-type semiconductor layer 12, an N-type semiconductor layer 14, a P-electrode 16, an N-electrode 18, and a luminescent layer 15.

In the embodiment illustrated in FIGS. 1A-1B, the test system 100 includes a carrier 30, a test electrode 40, a plurality of optical receivers 50, a power supply 60, and a judging unit 70. The carrier 30 is configured to hold the test electrode 40 and adjust the distance between the test electrode 40 and the luminance device 10. The power supply 60, coupled between the test electrode 40 and the N-electrode 18 of the luminance device 10, is configured to apply a first voltage to the test electrode 40 and apply a second voltage to the N-electrode 18, thereby establishing a voltage difference V_{BIAS} between the test electrode 40 and the N-electrode 18.

In the embodiment illustrated in FIGS. 2A-2B, the test system 200 includes a carrier 30, two test electrodes 41 and 42, a plurality of optical receivers 50, a power supply 60, and a judging unit 70. The test electrodes 41 and 42 with a pattern design are disposed on the carrier 30 at locations corresponding to the P-electrode 16 and the N-electrode 18, respectively. In other words, the distance between the test electrode 41 and the P-electrode 16 and the distance between the test electrode 42 and the N-electrode 18 may be adjusted by moving the carrier 30. The power supply 60, coupled between the test electrodes 41 and 42, is configured to apply a first voltage to the test electrode 41 and apply a second voltage to the test electrode 42, thereby establishing a voltage difference V_{BIAS} between the test electrodes 41 and 42.

The amount of the optical receivers 50 is related to the amount of the luminescent devices 10. Each optical receiver 50 is configured to detect the optical signals from one or multiple corresponding luminescent devices 10 when lit up. The judging unit 70 is configured to determine whether the luminescent devices 10 function normally according to the detecting result of each optical receiver 50 for subsequent repair process. In an embodiment, each luminescent device 10 may be accurately monitored by a corresponding optical receiver 50. In another embodiment, each optical receiver 50 is configured to monitor the status of multiple luminescent devices 10 within a specific region. However, the amount of the optical receivers 50 does not limit the scope of the present invention.

In an embodiment when the test system 100 is used to run a test flow, the power supply 60 is first turned on to establish the voltage difference V_{BIAS} between the test electrode 40 and the N-electrode 18 of the luminescent device 10. Next, the carrier 30 is moved in a way so that the test electrode 40 gradually approaches the P-electrode 16 of the luminescent device 10. Once the distance d between the test electrode 40 and the P-electrode 16 is reduced to a specific value (FIG. 1B depicts the case of d=0 in which the test electrode 40 is in contact with the P-electrode 16), the P-electrode 16 is able to sense the first voltage on the test electrode 40, and the voltage difference V_{BIAS} established between the P-electrode 16 and the N-electrode 18 may conduct the luminescent device 10. Under normal condition, the luminescent device 10 can be successfully lit up and emit optical signals which may be detected by the corresponding optical receiver 50. If the luminescent device 10 is flawed (such as due to defects, contamination or missing materials in devices) and cannot be lit up, the corresponding optical receiver 50 is unable to detect any optical signal. Therefore, the judging unit 70 may determine whether the luminescent devices 10 can function normally according to the detecting result of each optical receiver 50 for subsequent repair process.

In another embodiment when the test system 100 is used to run a test flow, the carrier 30 is first moved in a way so that the distance d between the test electrode 40 and the P-electrode 16 of the luminescent device 10 is reduced to a specific value (FIG. 1B depicts the case of d=0 in which the test electrode 40 is in contact with the P-electrode 16). Next, the power supply 60 is turned on to establish the voltage difference V_{BIAS} between the test electrode 40 and the N-electrode 18 of the luminescent device 10. Once the P-electrode 16 senses the first voltage on the test electrode 40, the voltage difference V_{BIAS} established between the P-electrode 16 and the N-electrode 18 may conduct the luminescent device 10. Under normal condition, the luminescent device 10 can be successfully lit up and emit optical signals which may be detected by the corresponding optical receiver 50. If the luminescent device 10 is flawed (such as due to defects, contamination or missing materials in devices) and cannot be lit up, the corresponding optical receiver 50 is unable to detect any optical signal. Therefore, the judging unit 70 may determine whether the luminescent devices 10 can function normally according to the detecting result of each optical receiver 50 for subsequent repair process.

In an embodiment when the test system 200 is used to run a test flow, the power supply 60 is first turned on to establish the voltage difference V_{BIAS} between the test electrodes 41 and 42. Next, the carrier 30 is moved in a way so that the test electrodes 41 and 42 gradually approach the P-electrode 16 and the N-electrode 18 of the luminescent device 10, respectively. Once the distance d1 between the test electrode 41 and the P-electrode 16 and the distance d2 between the test electrode 42 and the N-electrode 18 are reduced to a specific value (FIG. 2B depicts the case of d1=d2=0 in which the test electrode 41 is in contact with the P-electrode 16 and the test electrode 42 is in contact with the N-electrode 18), the P-electrode 16 is able to sense the first voltage on the test electrode 41 and the N-electrode 18 is able to sense the second voltage on the test electrode 42. The voltage difference V_{BIAS} established between the P-electrode 16 and the N-electrode 18 may thus conduct the luminescent device 10. Under normal condition, the luminescent device 10 can be successfully lit up and emit optical signals which may be detected by the corresponding optical receiver 50. If the luminescent device 10 is flawed (such as due to defects, contamination or missing materials in devices) and cannot be lit up, the corresponding optical receiver 50 is unable to detect any optical signal. Therefore, the judging unit 70 may determine whether the luminescent devices 10 can function normally according to the detecting result of each optical receiver 50 for subsequent repair process.

In another embodiment when the test system 200 is used to run a test flow, the carrier 30 is first moved in a way so that the distance d1 between the test electrode 41 and the P-electrode 16 and the distance d2 between the test electrode 42 and the N-electrode 18 are reduced to a specific value (FIG. 2B depicts the case of d1=d2=0 in which the test electrode 41 is in contact with the P-electrode 16 and the test electrode 42 is in contact with the N-electrode 18). Next, the power supply 60 is turned on to establish the voltage difference V_{BIAS} between the test electrodes 41 and 42. Once the P-electrode 16 senses the first voltage on the test electrode 41 and the N-electrode 18 senses the second voltage on the test electrode 42, the voltage difference V_{BIAS} established between the P-electrode 16 and the N-electrode 18 may thus conduct the luminescent device 10. Under normal condition, the luminescent device 10 can be successfully lit up and emit optical signals which may be detected by the corresponding optical receiver 50. If the luminescent device 10 is flawed (such as due to defects, contamination or missing materials in devices) and cannot be lit up, the corresponding optical receiver 50 is unable to detect any optical signal. Therefore, the judging unit 70 may determine whether the luminescent devices 10 can function normally according to the detecting result of each optical receiver 50 for subsequent repair process.

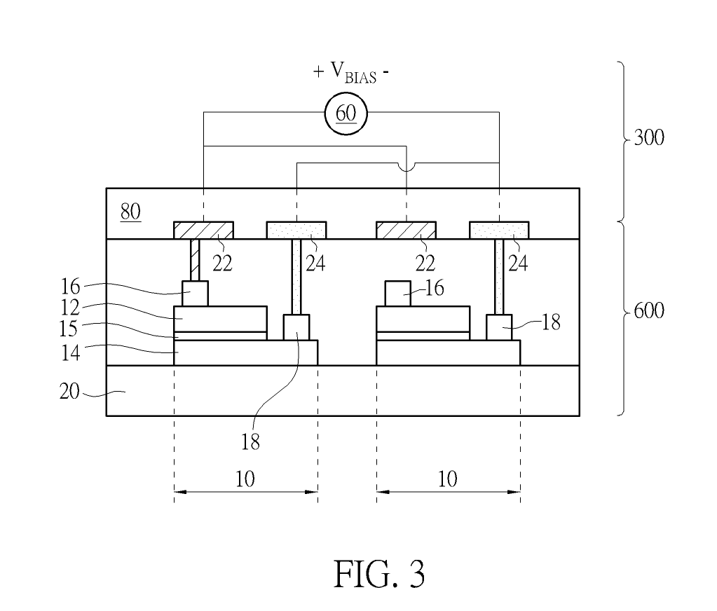

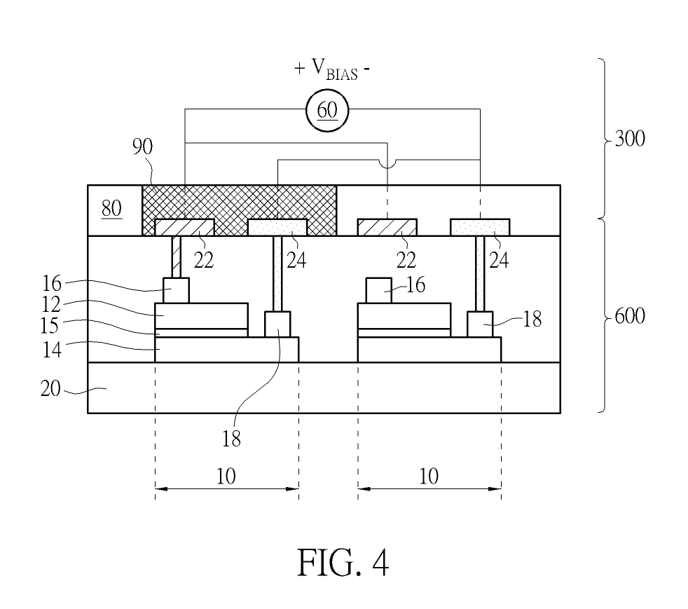

FIG. 3 and FIG. 4 are diagrams illustrating a testing system 300 for micro lighting device according to another embodiment of the present invention. The test system 300 may be apply to a micro lighting device 600 in order to detect anomalies such as defects, contamination or missing materials in devices.

The micro lighting device 600 with a thin-film, miniaturized and array design includes a plurality of luminescent devices (only two luminescent devices 10 are depicted for illustrative purpose), a drain line 22, and a ground line 24. The luminescent devices 10 are fabricated by combining P-type and N-type semiconductor materials before being mass transferred to be disposed on a substrate 20. Under normal condition, when a positive voltage is applied to the P-electrode and a negative voltage is applied to the N-electrode, electrons flow from the N-region towards the P-region and holes flow from the P-region towards the N-region due to the forward-bias voltage. These electrons and holes then combine in the PN junction of the luminescent layer, thereby emitting photons of light. In an embodiment of the present invention, each luminescent device 10 may be a micro LED device which includes a P-type semiconductor layer 12, an N-type semiconductor layer 14, a P-electrode 16, an N-electrode 18, and a luminescent layer 15, wherein the P-electrode 16 is electrically connected to the drain line 22 and the N-electrode 18 is electrically connected to the ground line 24.

In the embodiments illustrated in FIG. 3 and FIG. 4, the test system 300 includes a power supply 60 and a testing material layer 80. The power supply 60, coupled between the drains line 22 and the ground line 24, is configured to apply a first voltage to the P-electrode 16 and apply a second voltage to the N-electrode 18, thereby establishing a voltage difference V_{BIAS} between the P-electrode 16 and the N-electrode 18. The testing material layer 80 may be connected to the drain line 22 and the ground line 24 in a deposition, coating or attachment process. The color exhibited by the testing material layer 80 is associated with the luminous energy and the thermal energy provided by the corresponding luminance device 10.

In an embodiment, the testing material layer 80 may include thermochromatic materials including, but not limited to cholesteric liquid crystal, smectic liquid crystal, bismuth vanadate (Bivo4), iodide or Ni/SiO2 compound. In another embodiment, the testing material layer 80 may include photochromic materials including, but not limited to, photocatalysis chemical compounds (such as ZnO, WO3, CdS, Fe2O3 or TiO2), high molecular materials (such as spiropyran, fulgide, or diarylethene), or silver halide (AgX). However, the type of the thermochromatic/photochromic materials included in the testing material layer 80 does not limit the scope of the present invention.

After turning on the power supply 60, the voltage difference V_{BIAS} established between the P-electrodes 16 and the N-electrodes 18 may conduct the luminescent device 10. For illustrative purpose, it is assumed that the luminescent device 10 depicted on the left side of FIG. 3 and FIG. 4 can function normally, while the luminescent device 10 depicted on the right side of FIG. 3 and FIG. 4 is flawed (such as due to defects, contamination or missing materials in devices). When the normal luminescent device 10 on the left side is successfully lit up, it emits luminous energy and thermal energy which changes the color of the testing material layer 80 in a corresponding region, as depicted by the colored region 90 in FIG. 4. When the flawed luminescent device 10 on the right side is unable to light up, the color of the testing material layer 80 in a corresponding region remains unchanged. Therefore, the present invention may determine whether the luminescent devices 10 can function normally according to the color of the testing material layer 80 in the corresponding region for subsequent repair process.

In conclusion, the present invention provides a micro lighting device with repair mechanism in which flawed luminescent devices may be detected for subsequent repair process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A testing system for use in a micro lighting device, comprising:
a first test electrode;
a carrier configured to hold the first test electrode and adjust a distance between the first test electrode and a first electrode of a luminance device in the micro lighting device;
a power supply configured to apply a first voltage to the first test electrode and apply a second voltage to a second electrode of the luminance device;
an optical receiver configured to detect an optical signal of the luminance device; and
a judging unit configured to determine whether the luminance device is able to light up according to a detecting result of the optical receiver.

2. The testing system of claim 1, wherein the carrier is configured to shorten the distance between the first test electrode and the first electrode in a test flow until the first electrode is able to sense the first voltage on the first test electrode.

3. The testing system of claim 1, further comprising a second test electrode, wherein the first test electrode is disposed on the carrier at a first location corresponding to the first electrode and the second test electrode is disposed on the carrier at a second location corresponding to the second electrode.

4. The testing system of claim 3, wherein the carrier is configured to:
shorten the distance between the first test electrode and the first electrode in a test flow until the first electrode is able to sense the first voltage on the first test electrode; and
shorten a distance between the second test electrode and the second electrode in the test flow until the second electrode is able to sense the second voltage on the second test electrode.

5. The testing system of claim 1, wherein the luminescent device further comprises:
a first semiconductor layer of a first doping type, wherein the first electrode is disposed on the first semiconductor layer;
a first luminescent layer disposed on the first semiconductor layer; and
a second semiconductor layer of a second doping type disposed on the first luminescent layer, wherein the second electrode is disposed on the second semiconductor layer.

6. A testing system for use in a micro lighting device, comprising:
a power supply configured to apply a first voltage to a first electrode of a luminance device in the micro lighting device and apply a second voltage to a second electrode of the luminance device; and
a testing material layer disposed on the micro lighting device, wherein a color of the testing material layer is associated with at least one of luminous energy and thermal energy provided by the luminance device in the micro lighting device.

7. The testing system of claim 6, wherein:
the testing material layer exhibits a first color on a region corresponding to the luminance device when the luminance device is lit up;
the testing material layer exhibits a second color on the region corresponding to the luminance device when the luminance device is not lit up; and
the first color is different from the second color.

8. The testing system of claim 6, wherein the testing material layer includes a thermochromatic material or a photochromic material.

9. A method of testing a micro lighting device, comprising:
applying a first voltage to a first test electrode;
applying a second voltage to a first electrode of a luminance device in the micro lighting device;
adjusting a distance between the first test electrode and the luminance device until a second electrode of the luminance device is able to sense the first voltage; and
determining whether the luminance device is lit up by detecting an optical signal from the luminance device.

10. A method of testing a micro lighting device, comprising:
applying a first voltage to a first test electrode;
applying a second voltage to a second test electrode;
adjusting a distance between the first test electrode and a luminance device in the micro lighting device until a first electrode of the luminance device is able to sense the first voltage;
adjusting a distance between the second test electrode and the luminance device until a second electrode of the luminance device is able to sense the second voltage; and
determining whether the luminance device is lit up by detecting an optical signal from the luminance device.

11. A method of testing a micro lighting device, comprising:
fabricating a plurality of luminance devices and then transferring the plurality of luminance devices to be disposed on a substrate;
disposing a testing material layer on the plurality of luminance devices, wherein a color exhibited by the testing material layer on a region is associated with at least one of luminous energy and thermal energy received in the region;
applying a first voltage to a first electrode of each luminance device and applying a second voltage to a second electrode of each luminance device; and
determining whether each luminance device is lit up according to the color of each region corresponding to each luminance device.
